(19) United States
(12) Patent Application Publication
(10) Pub. No.: US 2024/0222298 A1
(43) Pub. Date: Jul. 4, 2024

(54) TECHNOLOGIES FOR DIE RECYCLING FOR HIGH YIELD PACKAGING

(71) Applicant: Intel Corporation, Santa Clara, CA (US)

(72) Inventors: Jeremy D. Ecton, Gilbert, AZ (US); Brandon Christian Marin, Gilbert, AZ (US); Srinivas V. Pietambaram, Chandler, AZ (US); Suddhasattwa Nad, Chandler, AZ (US); Gang Duan, Chandler, AZ (US)

(73) Assignee: Intel Corporation, Santa Clara, CA (US)

(21) Appl. No.: 18/091,583

(22) Filed: Dec. 30, 2022

(51) Int. Cl. H01L 23/00; H01L 23/498; H01L 23/538; H01L 25/065

(52) U.S. Cl. CPC H01L 24/08; H01L 23/49816; H01L 23/5381; H01L 24/05; H01L 24/80; H01L 25/0655; H01L 2224/05644; H01L 2224/05647; H01L 2224/08225; H01L 2224/80444; H01L 2224/8049; H01L 2924/0105; H01L 2924/0132

(57) ABSTRACT

Technologies for die recycling for high yield packaging is disclosed. In the illustrative embodiment, a release layer is deposited on one or more dies. The release layer includes conductive pads and a dielectric layer. Both the conductive pads and the dielectric layer have melting points between a temperature at which the die assembly will be processed and a temperature at which the die may sustain damage. One or more layers such as redistribution layers are deposited on the release layer. If a fault is discovered in the redistribution layers, the die assembly can be heated up past the melting point of the release layer, allowing the die to be removed. The die can then be cleaned and recycled for another packaging attempt.

### BACKGROUND

The demand for miniaturization of form factor and increased level of integration for high performance are driving sophisticated packaging techniques in the semiconductor industry. Die partitioning enables miniaturization of small form factor and high performance without yield issues, but such an approach requires fine die to die connections. Bridge dies that provide fine interconnects between other dies can enable lower cost packaging.

For fine bump pitches, a die first approach can be used. In a die first approach, a die is placed face up, and components such as redistribution layers are patterned directly on the die. However, any yield loss in forming the redistribution layers is costly, as it requires that the die be discarded.

### BRIEF DESCRIPTION OF THE DRAWINGS

FIG. 1 is an isometric view of an integrated circuit component.

FIG. 2 is a cross-sectional view of one embodiment of part of the integrated circuit component of FIG. 1.

FIGS. 3 and 4 are a simplified flow diagram of at least one embodiment of a method for manufacturing the integrated circuit component of FIG. 1.

FIG. 5 shows one stage of a method of manufacturing the integrated circuit component of FIG. 1.

FIG. 6 shows one stage of a method of manufacturing the integrated circuit component of FIG. 1.

FIG. 7 shows one stage of a method of manufacturing the integrated circuit component of FIG. 1.

FIG. 8 shows one stage of a method of manufacturing the integrated circuit component of FIG. 1.

FIG. 9 shows one stage of a method of manufacturing the integrated circuit component of FIG. 1.

FIG. 10 shows one stage of a method of manufacturing the integrated circuit component of FIG. 1.

FIG. 11 shows one stage of a method of manufacturing the integrated circuit component of FIG. 1.

FIG. 12 shows one stage of a method of manufacturing the integrated circuit component of FIG. 1.

FIG. 13 shows one stage of a method of manufacturing the integrated circuit component of FIG. 1.

FIG. 14 shows one stage of a method of manufacturing the integrated circuit component of FIG. 1.

FIG. 15 shows one stage of a method of manufacturing the integrated circuit component of FIG. 1.

FIG. 16 shows one stage of a method of manufacturing the integrated circuit component of FIG. 1.

FIG. 17 shows one stage of a method of manufacturing the integrated circuit component of FIG. 1.

FIG. 18 is a top view of a wafer and dies that may be included in a microelectronic assembly, in accordance with any of the embodiments disclosed herein.

FIG. 19 is a cross-sectional side view of an integrated circuit device that may be included in a microelectronic assembly, in accordance with any of the embodiments disclosed herein.

FIGS. 20A-20D are perspective views of example planar, gate-all-around, and stacked gate-all-around transistors.

FIG. 21 is a cross-sectional side view of an integrated circuit device assembly that may include a microelectronic assembly, in accordance with any of the embodiments disclosed herein.

FIG. 22 is a block diagram of an example electrical device that may include a microelectronic assembly, in accordance with any of the embodiments disclosed herein.

### DETAILED DESCRIPTION

In various embodiments disclosed herein, part of an integrated circuit component can be manufactured by building up components such as a redistribution layer directly on a integrated circuit die. A release layer is formed on the die before the redistribution layer. The release layer is made of components with a melting point that is above the processing temperature to make the redistribution layer and below a temperature which will damage the die. As a result, if the redistribution layer or other component built up on the die is faulty, the faulty components can be removed, and the die can be reused, increasing yield. The release layer including both conductive and dielectric parts, providing electrical connections and isolation, as required.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

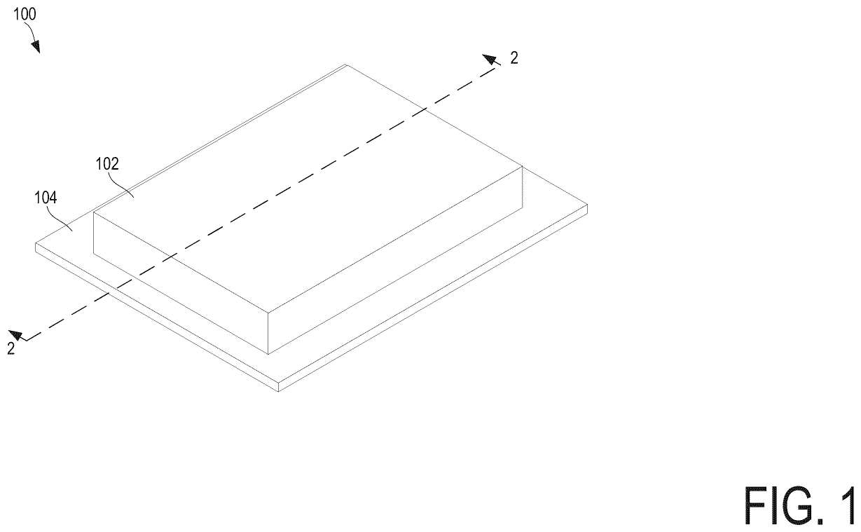

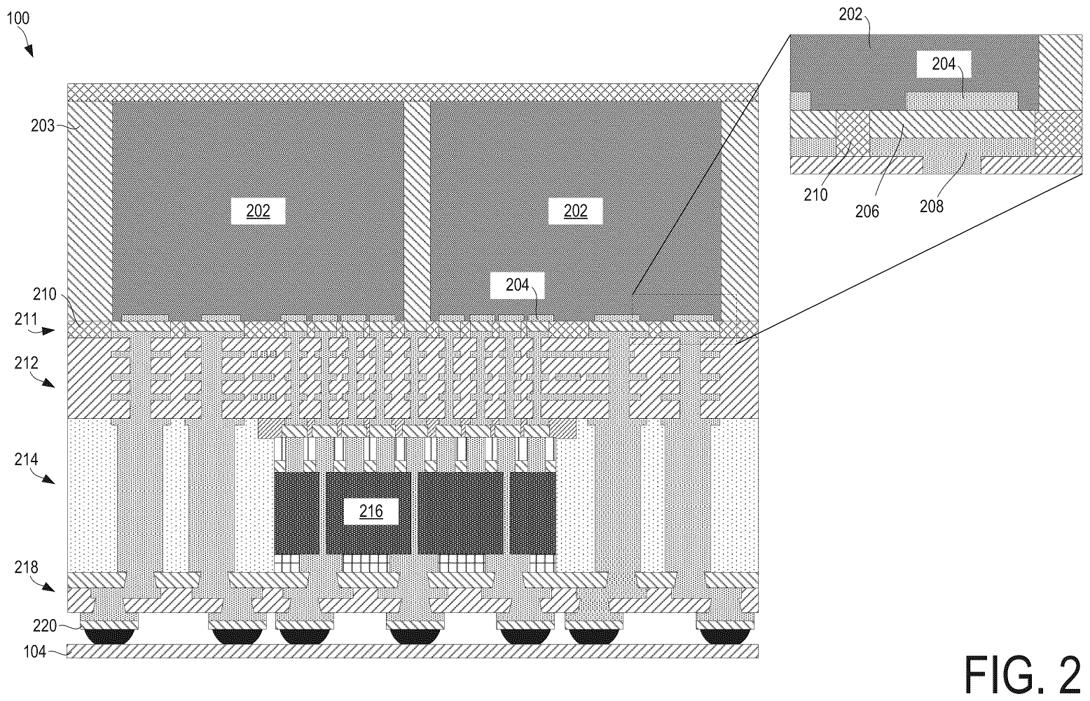

Referring now to FIGS. 1 and 2, in one embodiment, an integrated circuit component 100 includes a die assembly 102 and a substrate. FIG. 1 shows a perspective view of the integrated circuit component 100, and FIG. 2 shows a cross-sectional view of part of the integrated circuit component 100. The integrated circuit component 100 may be embodied as, included in, or include any suitable component or device, such as an electronic integrated circuit, a photonic integrated circuit, a processor module, a memory module, an application-specific integrated circuit, a field-programmable gate array (FPGA), a graphics processor, an accelerator, etc.

The illustrative substrate 104 may be embodied as a circuit board made from ceramic, glass, and/or organic-based materials with fiberglass and resin, such as FR-4. The circuit board 104 may have any suitable length or width, such as 10-500 millimeters. The circuit board 104 may have any suitable thickness, such as 0.2-5 millimeters. The circuit board 104 may support additional components besides the die assembly 102, such as additional electronic or photonic integrated circuit components, a processor unit, a memory device, an accelerator device, etc. The substrate 104 may embodied as any other suitable material, such as silicon. The integrated circuit component 100 may include a mid-level interconnect that connects to a substrate or a second-level interconnect that connects to a board, such as a motherboard. In some embodiments, the integrated circuit component 100 may not include a separate substrate 104.

As shown in FIG. 1, in the illustrative embodiment, the die assembly 102 may be covered by, e.g., a integrated heat spreader. In other embodiments, the various components of the die assembly 102 may not be covered or sealed.

Referring now to FIG. 2, a cross-sectional view of part of the integrated circuit component 100 is shown. The integrated circuit component 100 includes one or more dies 202, with mold 203 around the dies 202. The dies 202 have contact pads 204 for various electrical connections, such as signal connections or power connections. A redistribution layer 212 is below the dies 202. A release layer 211 is between the dies 202 and the redistribution layer 212. The releaser layer 211 includes conductive pads 206 and a dielectric layer 210. The conductive pads 206 are adjacent the contact pads 204 of the dies 202, and contact pads 208 of a redistribution layer 212 are adjacent the conductive pads 206. The dielectric layer 210 provides electrical isolation between the various contact pads 204, 208, conductive pads 206, and the dies 202 and the redistribution layer 212. In the illustrative embodiment, the contact pads 204, 208 are copper. In other embodiments, the copper pads 204, 208 may include a different material, such as gold.

The redistribution layer 212 is configured to provide electrical interconnect between various components of the integrated circuit component, such as between the dies 202, between the bridge die 216 and the dies 202, between the dies 202 and the bumps 220, etc.

Below the redistribution layer 212, in the illustrative embodiment, is a bridge layer 214. The bridge layer 214 includes a bridge die 216, which is connected to the dies 202 and other interconnects such as the bumps 220. The bridge die 216 provides interconnect circuitry for connections between the dies 202. The bridge die 216 may be embodied as, e.g., an embedded multi-die interconnect bridge (EMIB) or an omni-directional interconnect (ODI). The bridge layer 214 may also include pillars connecting the redistribution layer 212 to another interconnect layer, such as a backside redistribution layer 218. In some embodiments, a bridge die 216 or bridge layer 214 may not be included.

The backside redistribution layer 218 provides interconnects between the bridge layer 214 and solder bumps 220. The solder bumps 220 may connect to the substrate 104. It should be appreciated that, in some embodiments, some or all of the layers 212, 214, 218 may not be present, and/or additional layers may be present. For example, in one embodiment, a backside redistribution layer 218 and solder bumps 220 may be patterned directly on the release layer 211.

As discussed below in more detail, the redistribution layer 212, bridge layer 214, and backside redistribution layer 218 are all built up on the dies 202. Such an approach can improve performance, allowing for, e.g., denser interconnect connections with the dies 202. However, if one of the components of the redistribution layer 212, bridge layer 214, backside redistribution layer 218, etc., is faulty, then the die assembly 102 cannot be used. As the dies 202 are often the most costly component of the die assembly 102, reusing the dies 202 would be beneficial. In order to allow for the dies 202 to be removed from the rest of the die assembly 102 and reused, the release layer 211 is designed to allow the dies 202 to be removed from the rest of the die assembly. The illustrative release layer 211 is made of materials with a melting point between a process temperature for applying the redistribution layer 212, etc., and a temperature at which components of the die 202 may sustain damage. The maximum processing temperature for adding the redistribution layer 212, etc., may be, e.g., 250-300° C. In the illustrative embodiment, the maximum processing temperature is about 270° C. As such, both during processing and use of the integrated circuit component at temperatures below a threshold temperature of, e.g., 270-350° C., the release layer 211 secures the dies 202 to the redistribution layer 212. At temperatures above a threshold of, e.g., 270-350° C., the release layer 211 releases the dies 202 from the redistribution layer 212. The threshold temperature for releasing the release layer 211 is below a threshold temperature at which the dies 202 will be damaged, allowing the dies 200 to withstand the temperature at which the release layer 211 releases the dies 202.

In the illustrative embodiment, the conductive pads 206 of the release layer 211 are high-temperature solder, such as a tin-gold solder. The tin-gold solder may be 20% tin and 80% gold by weight. More generally, the tin-gold solder may be, e.g., 15-40% tin and 60-85% gold by weight, depending on the particular properties that are desired. The tin-gold solder may have a melting point of, e.g., 278° C. to 350° C. In the illustrative embodiment, the tin-gold solder may have a melting point of about 290° C. More generally, the conductive pads 206 of the release layer 211 may be made of any suitable material that is conductive, has a melting point (or otherwise stops adhering to the dies 202 and/or the redistribution layer 212) at a temperature between about 250° C. to 400° C.

In the illustrative embodiment, the dielectric layer 210 of the release layer 211 is a high-melting point polymer, such as polytetrafluoroethylene (PTFE), cyclobutanes, high density polyimide, etc. The dielectric layer 210 may include any suitable combination of elements, such as carbon and fluorine, carbon and nitrogen, carbon and hydrogen, carbon, oxygen, and nitrogen, and/or any suitable combination of those. The dielectric layer 210 may have a melting point (or otherwise stops adhering to the dies 202 and/or the redistribution layer 212) at a temperature between about 250° C. to 400° C. For example, in one embodiment, the dielectric layer 210 may be PTFE with a melting point of about 327° C.

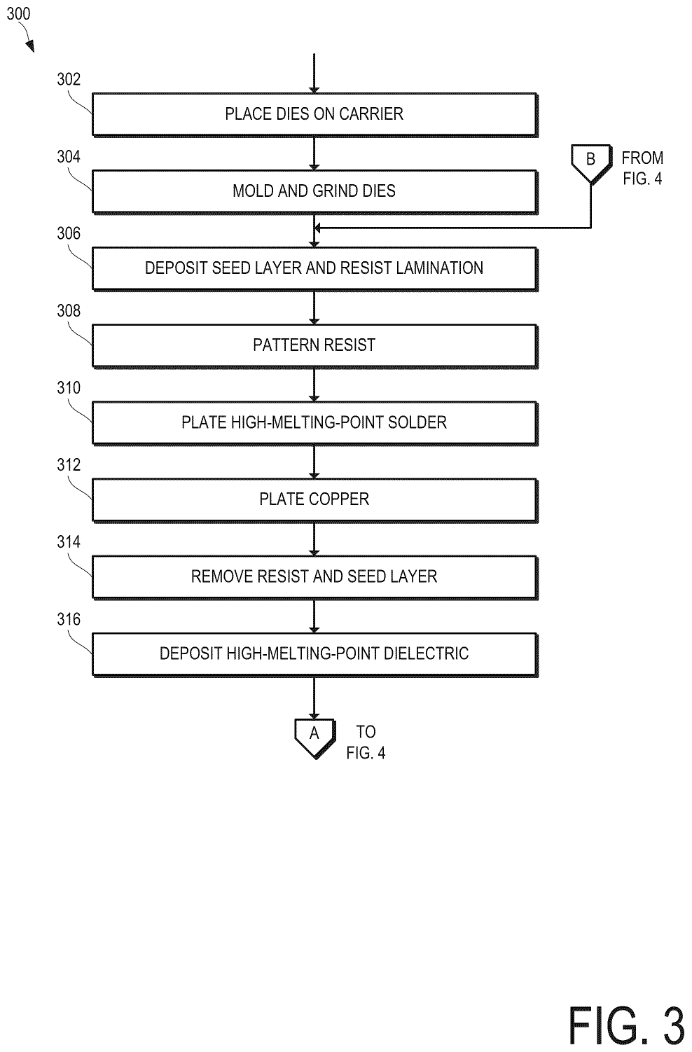

Referring now to FIG. 3, in one embodiment, a flowchart for a method 300 for creating the integrated circuit component 100 with a release layer 211 is shown. The method 300 may be executed by a technician and/or by one or more automated machines. In some embodiments, one or more machines may be programmed to do some or all of the steps of the method 300. Such a machine may include, e.g., a memory, a processor, data storage, etc. The memory and/or data storage may store instructions that, when executed by the machine, causes the machine to perform some or all of the steps of the method 300. The method 300 may use any suitable set of techniques that are used in semiconductor processing, such as chemical vapor deposition, atomic layer deposition, physical layer deposition, molecular beam epitaxy, layer transfer, photolithography, ion implantation, dry etching, wet etching, selective laser etching, thermal treatments, flip chip, magnetron sputter deposition, pulsed laser deposition, etc. It should be appreciated that the method 300 is merely one embodiment of a method to create one embodiment of the integrated circuit component 100, and other methods may be used to create any suitable embodiment of the integrated circuit component 100. In some embodiments, steps of the method 300 may be performed in a different order than that shown in the flowchart. Although described below as creating one integrated circuit component 100, in some embodiments, several sets of dies 202 may have some or all of the packaging steps performed in a batch at the same time.

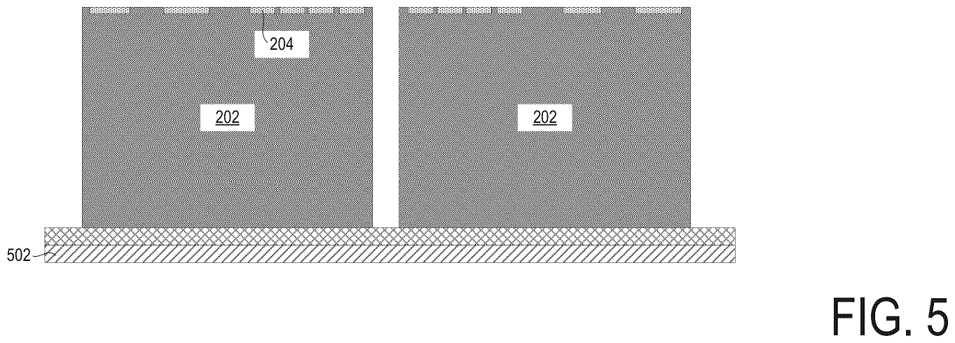

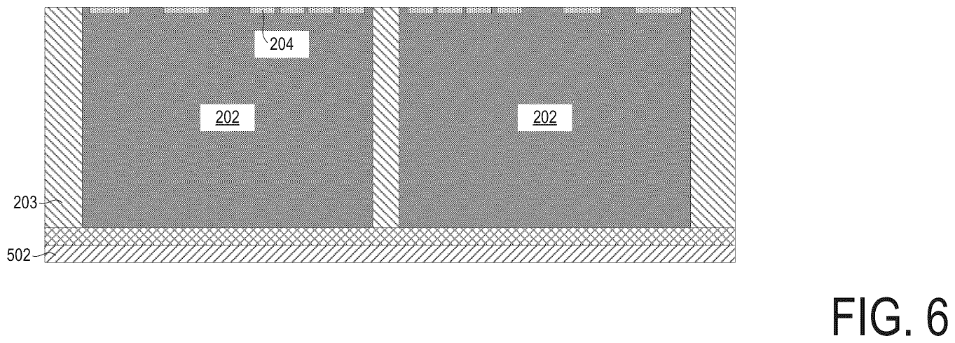

The method 300 begins in block 302, in which one or more dies 202 are placed on a carrier 502, as shown in FIG. 5. Mold 203 is deposited around the dies 202 and ground to expose the dies 202, as shown in FIG. 6.

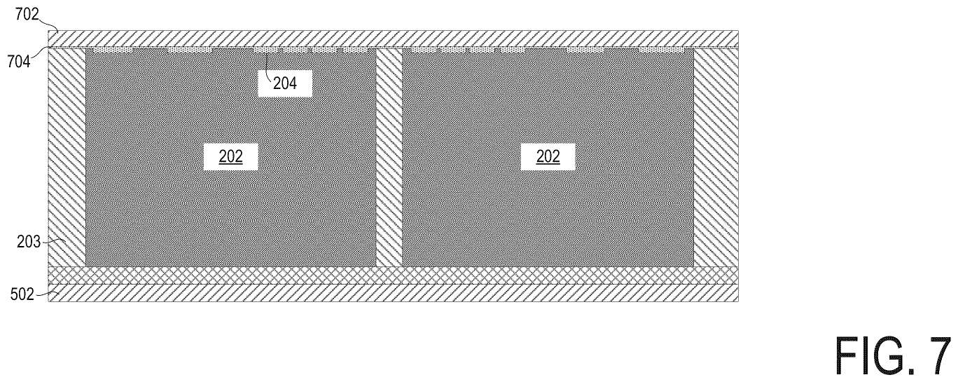

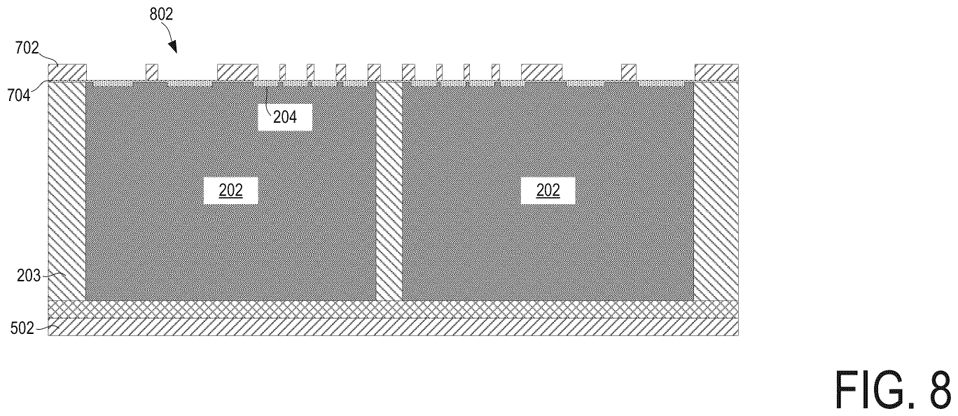

A seed layer 704, such as a copper seed layer 704, is then deposited on the dies 202, as shown in FIG. 7. A resist lamination layer 702 is placed over the seed layer 704. Several holes 802 are patterned in the resist in block 308, as shown in FIG. 8.

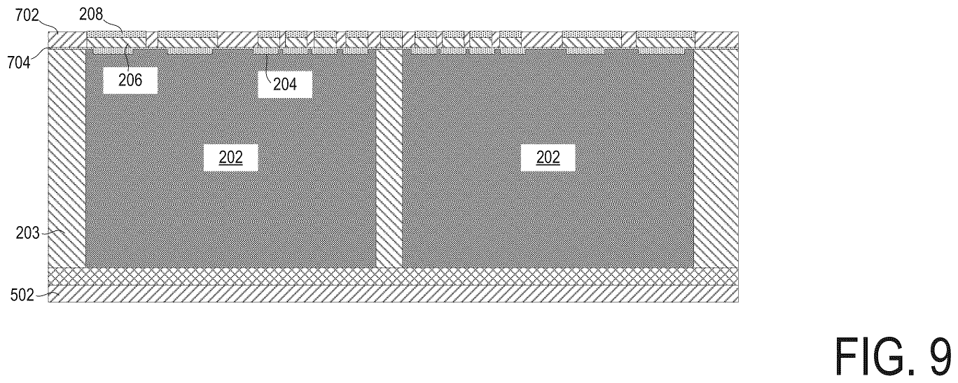

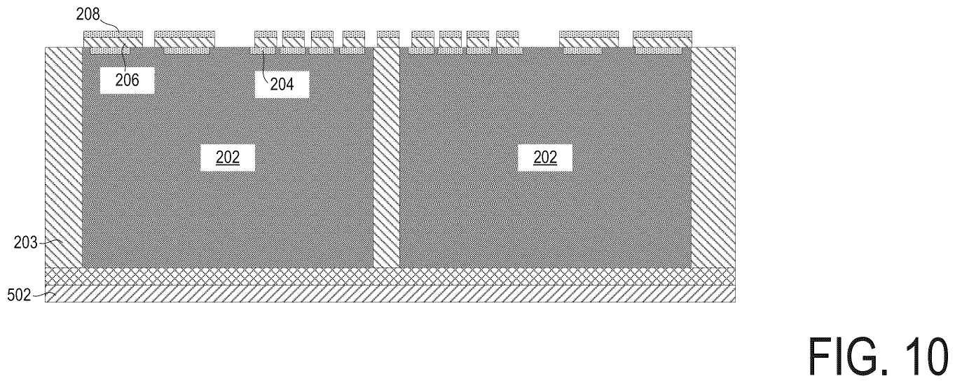

In block 310, a high-melting-point solder is deposited to form the conductive pads 206, as shown in FIG. 9. In block 312, copper is plated on top to form contact pads 208. The resist 702 and seed layer 704 are then removed in block 314, as shown in FIG. 10.

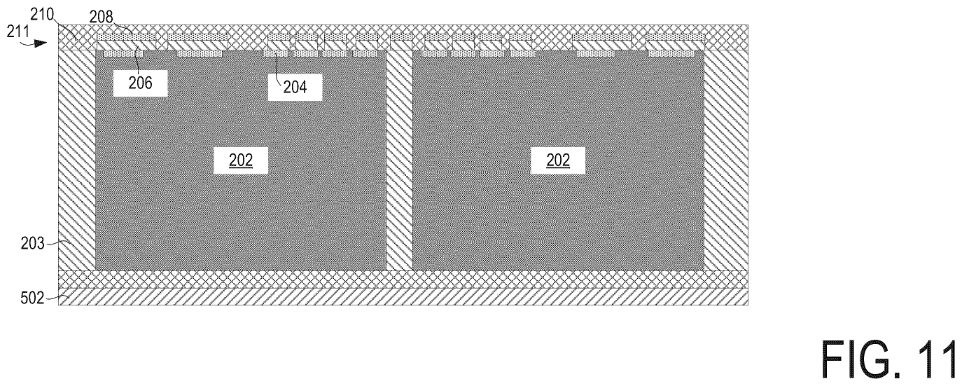

In block 316, a high-melting-point dielectric, such as PTFE, is deposited to form the dielectric layer 210 of the release layer 211, as shown in FIG. 11. The dielectric layer 210 is thinned (such as by etching, grinding, or polishing) to expose the contact pads 208.

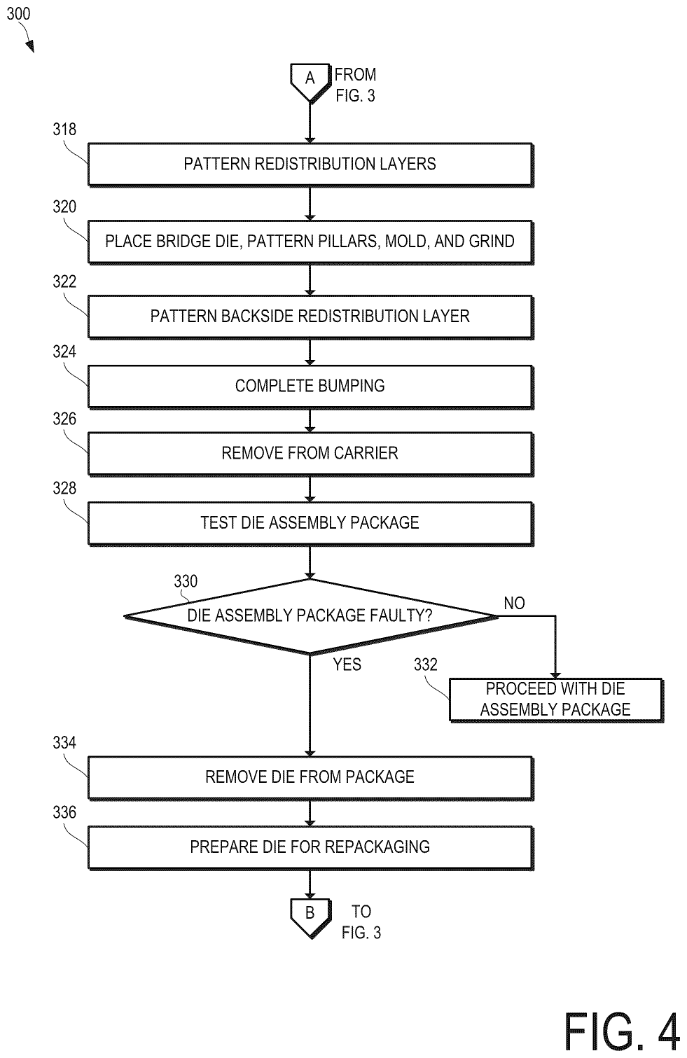

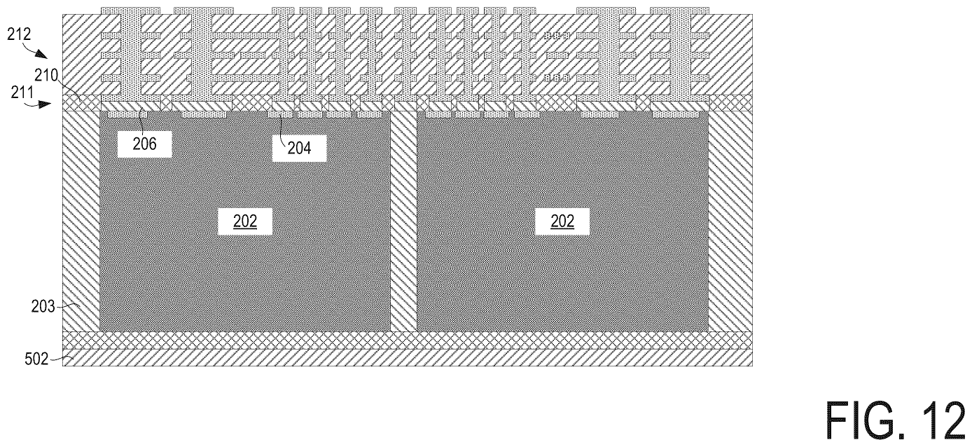

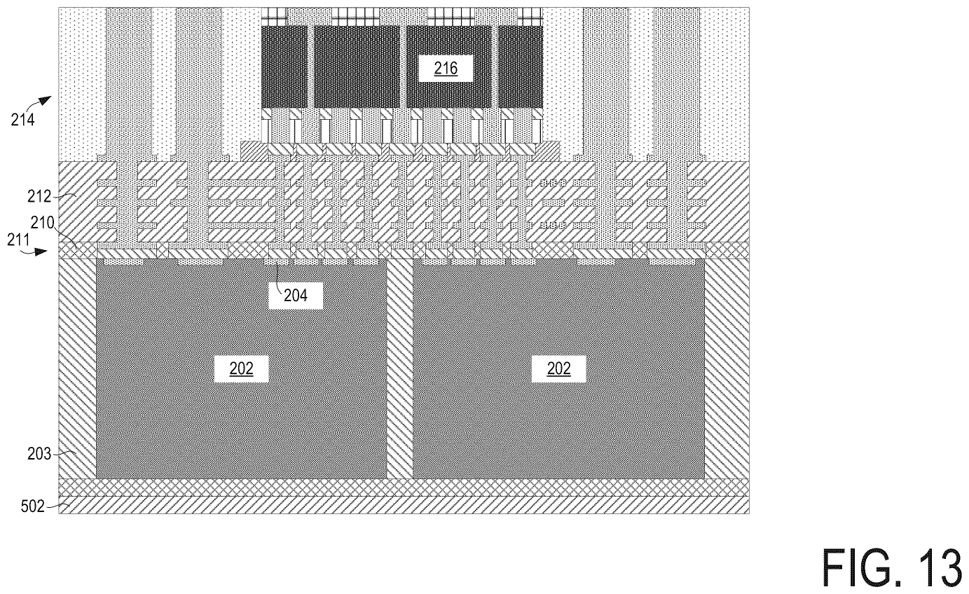

Referring now to FIG. 4, in block 318, the redistribution layer 212 is patterned onto the dies 202, as shown in FIG. 12. In block 320, the bridge die 216 is placed, the pillars are patterned, and mold is deposited and ground down, forming the bridge layer 214, as shown in FIG. 13.

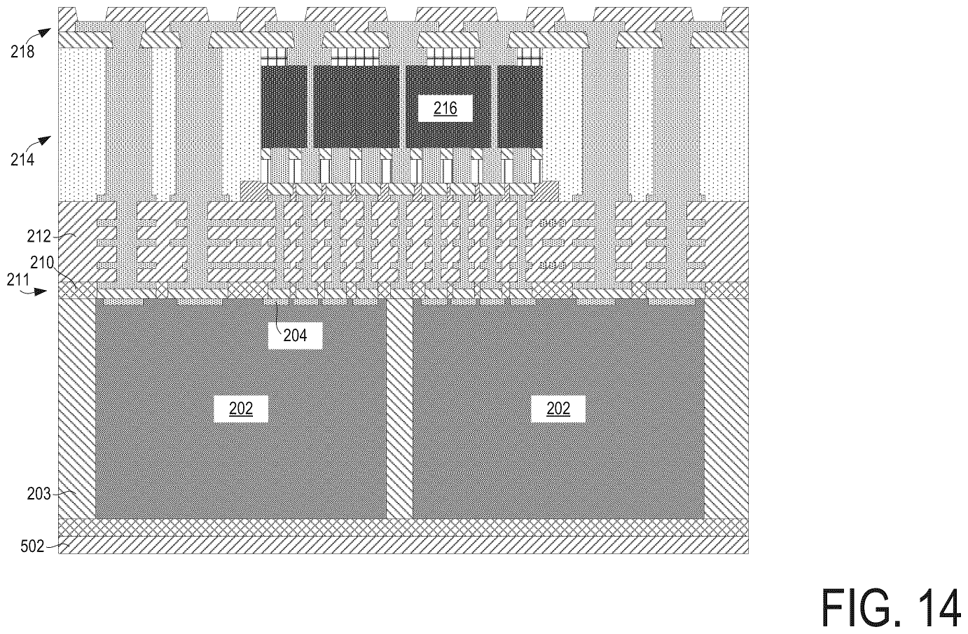

In block 322, the backside redistribution layer 218 is deposited, as shown in FIG. 14. The die assembly 102 is completed with die bumping in block 324. The die assembly 102 is removed from the carrier 502 in block 316. The die assembly 102 may be mounted on a substrate 104 as shown in FIGS. 1 and 2.

In block 328, the die assembly package 102 is tested. For example, the integrated circuit component 100 with the substrate 104 may be placed in a test stand to check for, e.g., correct operation of the various interconnects. In block 330, if the die assembly package is not faulty, the method 300 proceeds to block 332, in which further operations with the die assembly package can proceed, such as using the integrated circuit component 100, integrating the integrated circuit component 100 into another component, packaging the integrated circuit component 100 for sale, etc.

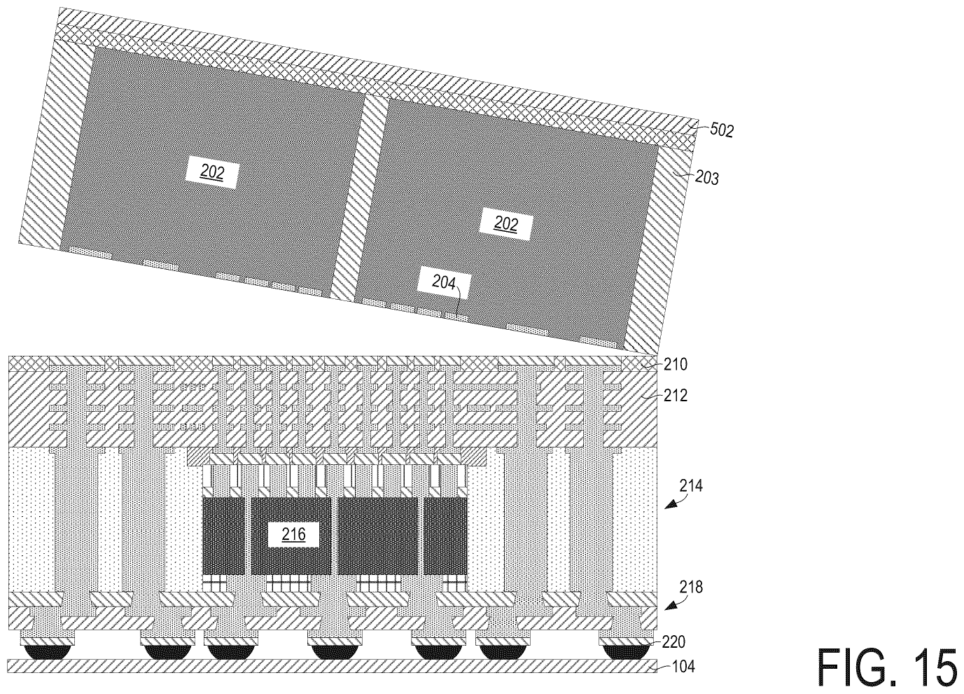

If the die assembly package 102 is faulty, the method 300 proceeds to block 334, in which the dies 202 are removed from the die assembly package 102, as shown in FIG. 15. In the illustrative embodiment, the die assembly package 102 is heated above a melting point of the dielectric layer 210 and the conductive pads 206 of the release layer 211, releasing the dies 202 from the rest of the die assembly package 102. In the illustrative embodiment, the die assembly package 102 is heated to over the 327° C. melting point of the dielectric layer 210. In other embodiments, the die assembly package 102 may be heated to a temperature of, e.g., 300-400° C.

In block 336, the dies 202 are prepared for repackaging, such as being polished to remove any residue from the release layer 211. The method 300 then loops back to block 306 in FIG. 3 to deposit a seed layer 704 and resist lamination 702.

Although the method 300 describes fully forming the integrated circuit component 100 before testing for faults, it should be appreciated that testing may be performed at any suitable time, such as after patterning the redistribution layer 212 and before forming the bridge layer 214.

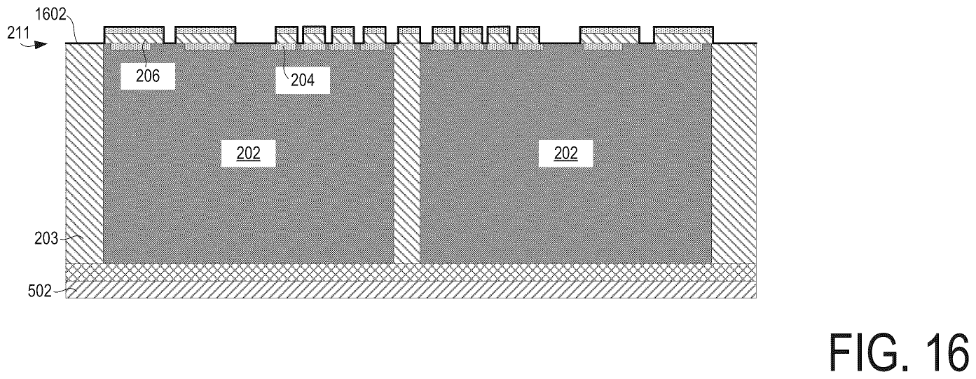

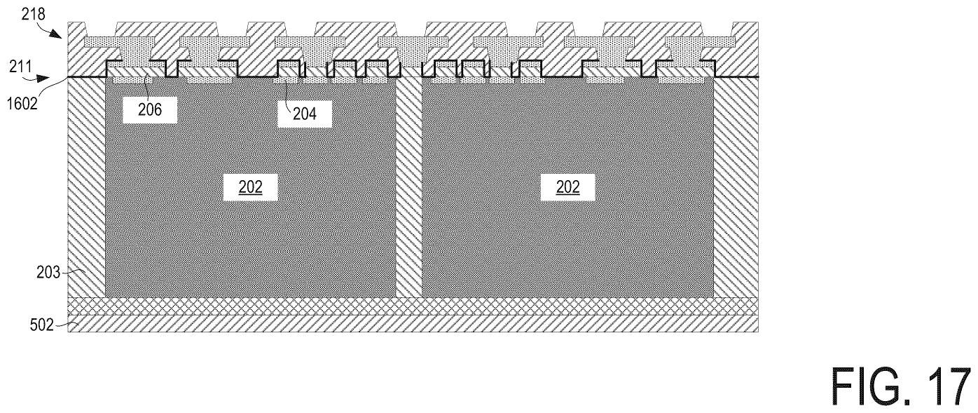

In some embodiments, rather than a relatively thick dielectric layer 210 between the dies 202 and the redistribution layer 212 as shown in FIG. 2, the release layer 211 includes a relatively thin dielectric release film 1602 may be a thin layer, as shown in FIG. 16. The dielectric release film 1602 may have a thickness of, e.g., less than five micrometers. In other embodiments, the dielectric release film 1602 may have a thickness of 1-30 micrometers. After the dielectric release film 1602 is deposited, as it can be laser drilled or dry etched to expose the contact pads 208, allowing for, e.g., a backside redistribution layer 218 to be deposited on top of it, as shown in FIG. 17. In some embodiments, some or all of the other dielectric material on the die assembly package 102 may be made of the same material as the release layer 211.

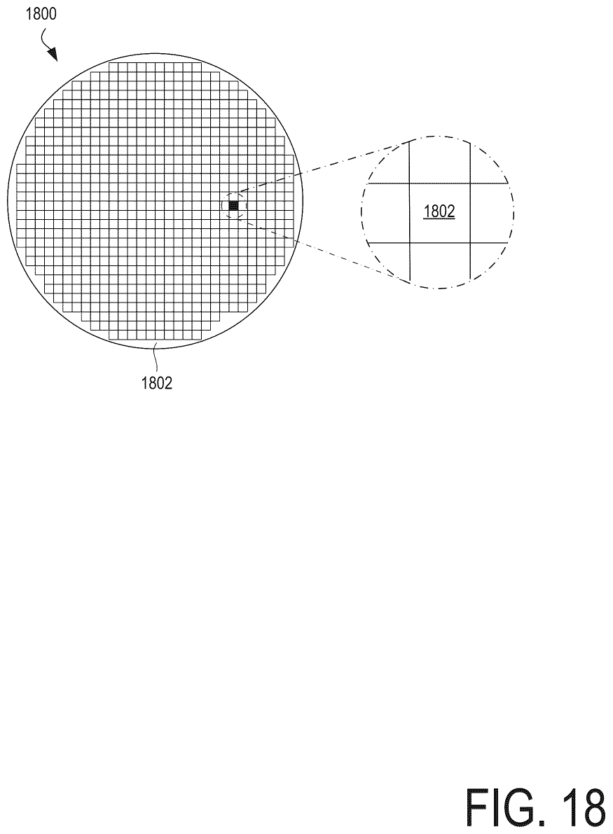

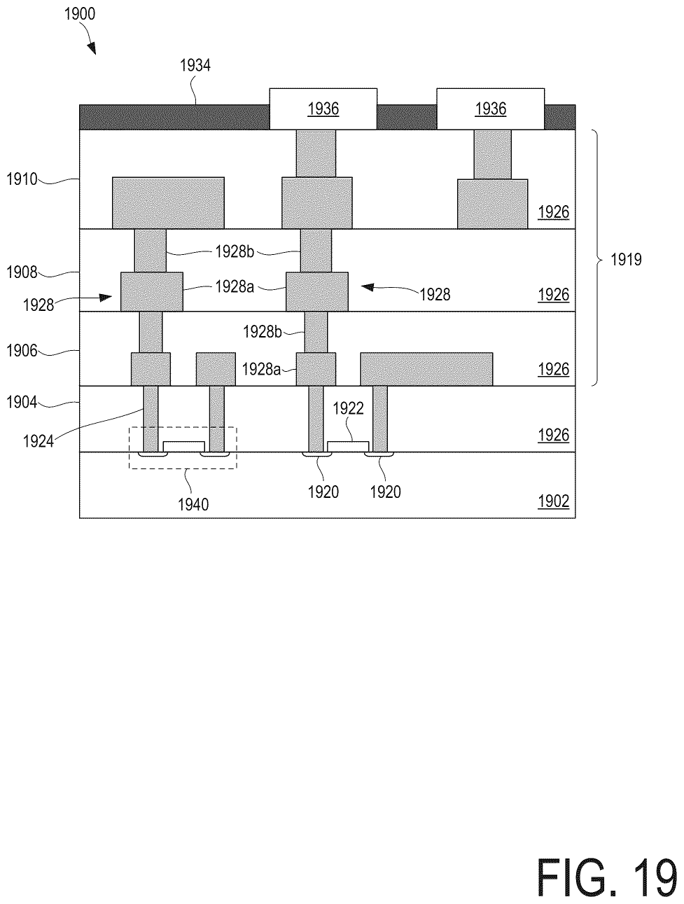

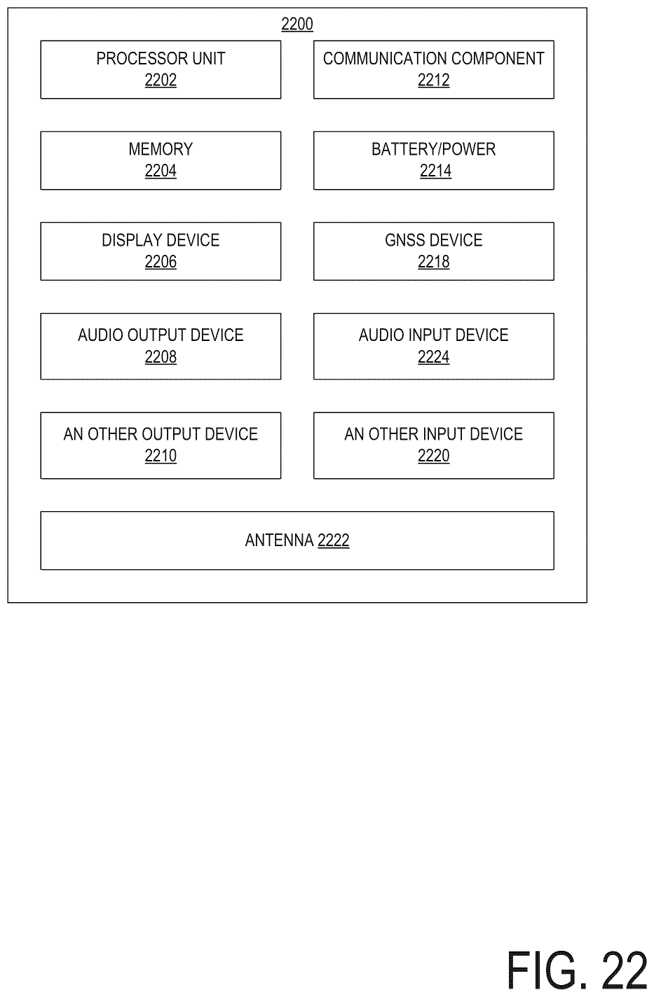

FIG. 18 is a top view of a wafer 1800 and dies 1802 that may be included in any of the integrated circuit components 100 disclosed herein (e.g., as any suitable ones of the dies 202). The wafer 1800 may be composed of semiconductor material and may include one or more dies 1802 having integrated circuit structures formed on a surface of the wafer 1800. The individual dies 1802 may be a repeating unit of an integrated circuit product that includes any suitable integrated circuit. After the fabrication of the semiconductor product is complete, the wafer 1800 may undergo a singulation process in which the dies 1802 are separated from one another to provide discrete “chips” of the integrated circuit product. The die 1802 may be any of the dies 202 disclosed herein. The die 1802 may include one or more transistors (e.g., some of the transistors 1940 of FIG. 19, discussed below), supporting circuitry to route electrical signals to the transistors, passive components (e.g., signal traces, resistors, capacitors, or inductors), and/or any other integrated circuit components. In some embodiments, the wafer 1800 or the die 1802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1802. For example, a memory array formed by multiple memory devices may be formed on a same die 1802 as a processor unit (e.g., the processor unit 2202 of FIG. 22) or other logic that is configured to store information in the memory devices or execute instructions stored in the memory array. Various ones of the integrated circuit components 100 disclosed herein may be manufactured using a die-to-wafer assembly technique in which some dies 202 are attached to a wafer 1800 that include others of the dies 202, and the wafer 1800 is subsequently singulated.

FIG. 19 is a cross-sectional side view of an integrated circuit device 1900 that may be included in any of the integrated circuit components 100 disclosed herein (e.g., in any of the dies 202). One or more of the integrated circuit devices 1900 may be included in one or more dies 1802 (FIG. 18). The integrated circuit device 1900 may be formed on a die substrate 1902 (e.g., the wafer 1800 of FIG. 18) and may be included in a die (e.g., the die 1802 of FIG. 18). The die substrate 1902 may be a semiconductor substrate composed of semiconductor material systems including, for example, n-type or p-type materials systems (or a combination of both). The die substrate 1902 may include, for example, a crystalline substrate formed using a bulk silicon or a silicon-on-insulator (SOI) substructure. In some embodiments, the die substrate 1902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1902. Although a few examples of materials from which the die substrate 1902 may be formed are described here, any material that may serve as a foundation for an integrated circuit device 1900 may be used. The die substrate 1902 may be part of a singulated die (e.g., the dies 1802 of FIG. 18) or a wafer (e.g., the wafer 1800 of FIG. 18).

The integrated circuit device 1900 may include one or more device layers 1904 disposed on the die substrate 1902. The device layer 1904 may include features of one or more transistors 1940 (e.g., metal oxide semiconductor field-effect transistors (MOSFETs)) formed on the die substrate 1902. The transistors 1940 may include, for example, one or more source and/or drain (S/D) regions 1920, a gate 1922 to control current flow between the S/D regions 1920, and one or more S/D contacts 1924 to route electrical signals to/from the S/D regions 1920. The transistors 1940 may include additional features not depicted for the sake of clarity, such as device isolation regions, gate contacts, and the like. The transistors 1940 are not limited to the type and configuration depicted in FIG. 19 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

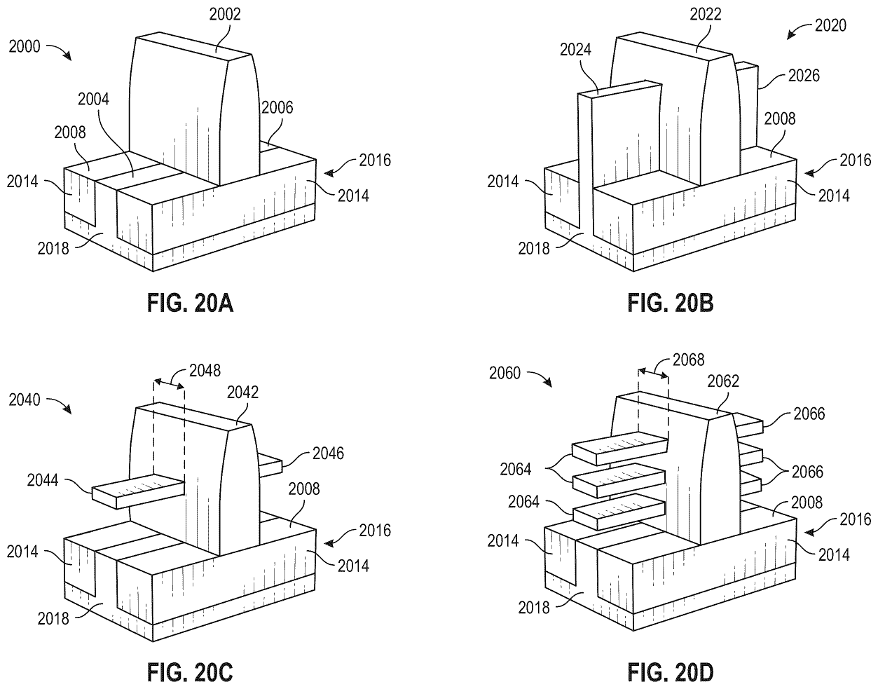

FIGS. 20A-20D are simplified perspective views of example planar, FinFET, gate-all-around, and stacked gate-all-around transistors. The transistors illustrated in FIGS. 20A-20D are formed on a substrate 2016 having a surface 2008. Isolation regions 2014 separate the source and drain regions of the transistors from other transistors and from a bulk region 2018 of the substrate 2016.

FIG. 20A is a perspective view of an example planar transistor 2000 comprising a gate 2002 that controls current flow between a source region 2004 and a drain region 2006. The transistor 2000 is planar in that the source region 2004 and the drain region 2006 are planar with respect to the substrate surface 2008.

FIG. 20B is a perspective view of an example FinFET transistor 2020 comprising a gate 2022 that controls current flow between a source region 2024 and a drain region 2026. The transistor 2020 is non-planar in that the source region 2024 and the drain region 2026 comprise “fins” that extend upwards from the substrate surface 2028. As the gate 2022 encompasses three sides of the semiconductor fin that extends from the source region 2024 to the drain region 2026, the transistor 2020 can be considered a tri-gate transistor. FIG. 20B illustrates one S/D fin extending through the gate 2022, but multiple S/D fins can extend through the gate of a FinFET transistor.

FIG. 20C is a perspective view of a gate-all-around (GAA) transistor 2040 comprising a gate 2042 that controls current flow between a source region 2044 and a drain region 2046. The transistor 2040 is non-planar in that the source region 2044 and the drain region 2046 are elevated from the substrate surface 2028.

FIG. 20D is a perspective view of a GAA transistor 2060 comprising a gate 2062 that controls current flow between multiple elevated source regions 2064 and multiple elevated drain regions 2066. The transistor 2060 is a stacked GAA transistor as the gate controls the flow of current between multiple elevated S/D regions stacked on top of each other. The transistors 2040 and 2060 are considered gate-all-around transistors as the gates encompass all sides of the semiconductor portions that extends from the source regions to the drain regions. The transistors 2040 and 2060 can alternatively be referred to as nanowire, nanosheet, or nanoribbon transistors depending on the width (e.g., widths 2048 and 2068 of transistors 2040 and 2060, respectively) of the semiconductor portions extending through the gate.

Returning to FIG. 19, a transistor 1940 may include a gate 1922 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1940 along the source-channel-drain direction, the gate electrode may consist of a U-shaped structure that includes a bottom portion substantially parallel to the surface of the die substrate 1902 and two sidewall portions that are substantially perpendicular to the top surface of the die substrate 1902. In other embodiments, at least one of the metal layers that form the gate electrode may simply be a planar layer that is substantially parallel to the top surface of the die substrate 1902 and does not include sidewall portions substantially perpendicular to the top surface of the die substrate 1902. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1920 may be formed within the die substrate 1902 adjacent to the gate 1922 of individual transistors 1940. The S/D regions 1920 may be formed using an implantation/diffusion process or an etching/deposition process, for example. In the former process, dopants such as boron, aluminum, antimony, phosphorous, or arsenic may be ion-implanted into the die substrate 1902 to form the S/D regions 1920. An annealing process that activates the dopants and causes them to diffuse farther into the die substrate 1902 may follow the ion-implantation process. In the latter process, the die substrate 1902 may first be etched to form recesses at the locations of the S/D regions 1920. An epitaxial deposition process may then be carried out to fill the recesses with material that is used to fabricate the S/D regions 1920. In some implementations, the S/D regions 1920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1920 may be formed using one or more alternate semiconductor materials such as germanium or a group III-V material or alloy. In further embodiments, one or more layers of metal and/or metal alloys may be used to form the S/D regions 1920.

Electrical signals, such as power and/or input/output (I/O) signals, may be routed to and/or from the devices (e.g., transistors 1940) of the device layer 1904 through one or more interconnect layers disposed on the device layer 1904 (illustrated in FIG. 19 as interconnect layers 1906-1910). For example, electrically conductive features of the device layer 1904 (e.g., the gate 1922 and the S/D contacts 1924) may be electrically coupled with the interconnect structures 1928 of the interconnect layers 1906-1910. The one or more interconnect layers 1906-1910 may form a metallization stack (also referred to as an “ILD stack”) 1919 of the integrated circuit device 1900.

The interconnect structures 1928 may be arranged within the interconnect layers 1906-1910 to route electrical signals according to a wide variety of designs; in particular, the arrangement is not limited to the particular configuration of interconnect structures 1928 depicted in FIG. 19. Although a particular number of interconnect layers 1906-1910 is depicted in FIG. 19, embodiments of the present disclosure include integrated circuit devices having more or fewer interconnect layers than depicted.

In some embodiments, the interconnect structures 1928 may include lines 1928a and/or vias 1928b filled with an electrically conductive material such as a metal. The lines 1928a may be arranged to route electrical signals in a direction of a plane that is substantially parallel with a surface of the die substrate 1902 upon which the device layer 1904 is formed. For example, the lines 1928a may route electrical signals in a direction in and out of the page and/or in a direction across the page. The vias 1928b may be arranged to route electrical signals in a direction of a plane that is substantially perpendicular to the surface of the die substrate 1902 upon which the device layer 1904 is formed. In some embodiments, the vias 1928b may electrically couple lines 1928a of different interconnect layers 1906-1910 together.

The interconnect layers 1906-1910 may include a dielectric material 1926 disposed between the interconnect structures 1928, as shown in FIG. 19. In some embodiments, dielectric material 1926 disposed between the interconnect structures 1928 in different ones of the interconnect layers 1906-1910 may have different compositions; in other embodiments, the composition of the dielectric material 1926 between different interconnect layers 1906-1910 may be the same. The device layer 1904 may include a dielectric material 1926 disposed between the transistors 1940 and a bottom layer of the metallization stack as well. The dielectric material 1926 included in the device layer 1904 may have a different composition than the dielectric material 1926 included in the interconnect layers 1906-1910; in other embodiments, the composition of the dielectric material 1926 in the device layer 1904 may be the same as a dielectric material 1926 included in any one of the interconnect layers 1906-1910.

A first interconnect layer 1906 (referred to as Metal 1 or “M1”) may be formed directly on the device layer 1904. In some embodiments, the first interconnect layer 1906 may include lines 1928a and/or vias 1928b, as shown. The lines 1928a of the first interconnect layer 1906 may be coupled with contacts (e.g., the S/D contacts 1924) of the device layer 1904. The vias 1928b of the first interconnect layer 1906 may be coupled with the lines 1928a of a second interconnect layer 1908.

The second interconnect layer 1908 (referred to as Metal 2 or “M2”) may be formed directly on the first interconnect layer 1906. In some embodiments, the second interconnect layer 1908 may include via 1928b to couple the lines 1928 of the second interconnect layer 1908 with the lines 1928a of a third interconnect layer 1910. Although the lines 1928a and the vias 1928b are structurally delineated with a line within individual interconnect layers for the sake of clarity, the lines 1928a and the vias 1928b may be structurally and/or materially contiguous (e.g., simultaneously filled during a dual-damascene process) in some embodiments.

The third interconnect layer 1910 (referred to as Metal 3 or “M3”) (and additional interconnect layers, as desired) may be formed in succession on the second interconnect layer 1908 according to similar techniques and configurations described in connection with the second interconnect layer 1908 or the first interconnect layer 1906. In some embodiments, the interconnect layers that are “higher up” in the metallization stack 1919 in the integrated circuit device 1900 (i.e., farther away from the device layer 1904) may be thicker that the interconnect layers that are lower in the metallization stack 1919, with lines 1928a and vias 1928b in the higher interconnect layers being thicker than those in the lower interconnect layers.

The integrated circuit device 1900 may include a solder resist material 1934 (e.g., polyimide or similar material) and one or more conductive contacts 1936 formed on the interconnect layers 1906-1910. In FIG. 19, the conductive contacts 1936 are illustrated as taking the form of bond pads. The conductive contacts 1936 may be electrically coupled with the interconnect structures 1928 and configured to route the electrical signals of the transistor(s) 1940 to external devices. For example, solder bonds may be formed on the one or more conductive contacts 1936 to mechanically and/or electrically couple an integrated circuit die including the integrated circuit device 1900 with another component (e.g., a printed circuit board). The integrated circuit device 1900 may include additional or alternate structures to route the electrical signals from the interconnect layers 1906-1910; for example, the conductive contacts 1936 may include other analogous features (e.g., posts) that route the electrical signals to external components. The conductive contacts 1936 may serve as the conductive contacts 204 or 208, as appropriate.

In some embodiments in which the integrated circuit device 1900 is a double-sided die, the integrated circuit device 1900 may include another metallization stack (not shown) on the opposite side of the device layer(s) 1904. This metallization stack may include multiple interconnect layers as discussed above with reference to the interconnect layers 1906-1910, to provide conductive pathways (e.g., including conductive lines and vias) between the device layer(s) 1904 and additional conductive contacts (not shown) on the opposite side of the integrated circuit device 1900 from the conductive contacts 1936. These additional conductive contacts may serve as the conductive contacts 204 or 208, as appropriate.

In other embodiments in which the integrated circuit device 1900 is a double-sided die, the integrated circuit device 1900 may include one or more through silicon vias (TSVs) through the die substrate 1902; these TSVs may make contact with the device layer(s) 1904, and may provide conductive pathways between the device layer(s) 1904 and additional conductive contacts (not shown) on the opposite side of the integrated circuit device 1900 from the conductive contacts 1936. These additional conductive contacts may serve as the conductive contacts 204 or 208, as appropriate. In some embodiments, TSVs extending through the substrate can be used for routing power and ground signals from conductive contacts on the opposite side of the integrated circuit device 1900 from the conductive contacts 1936 to the transistors 1940 and any other components integrated into the die 1900, and the metallization stack 1919 can be used to route I/O signals from the conductive contacts 1936 to transistors 1940 and any other components integrated into the die 1900.

Multiple integrated circuit devices 1900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

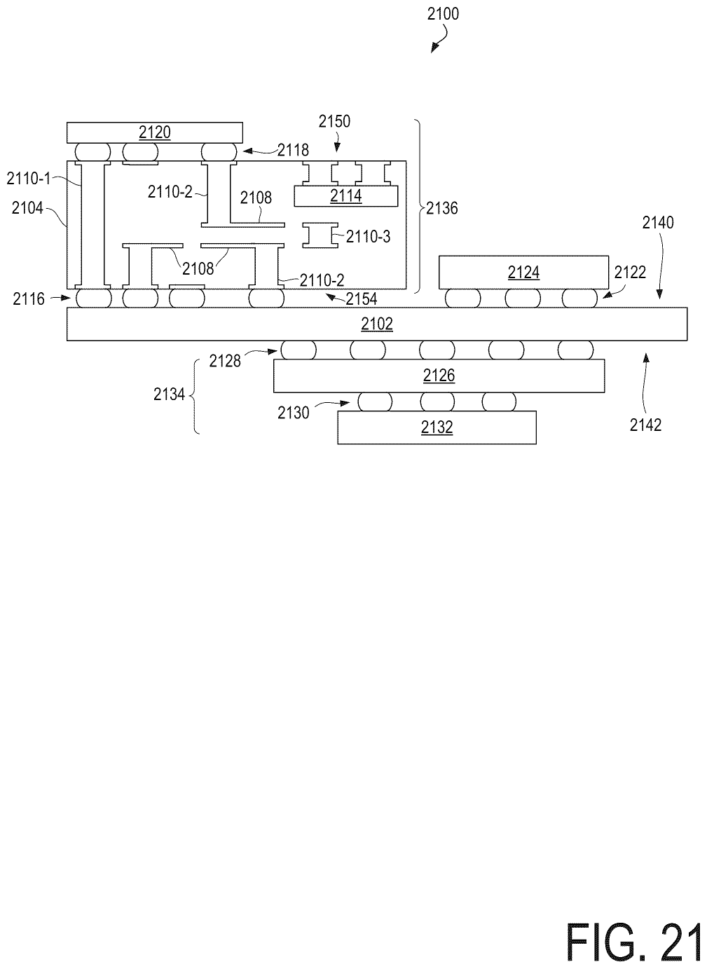

FIG. 21 is a cross-sectional side view of an integrated circuit device assembly 2100 that may include any of the integrated circuit components 100 disclosed herein. In some embodiments, the integrated circuit device assembly 2100 may be an integrated circuit component 100. The integrated circuit device assembly 2100 includes a number of components disposed on a circuit board 2102 (which may be a motherboard, system board, mainboard, etc.). The integrated circuit device assembly 2100 includes components disposed on a first face 2140 of the circuit board 2102 and an opposing second face 2142 of the circuit board 2102; generally, components may be disposed on one or both faces 2140 and 2142. Any of the integrated circuit components discussed below with reference to the integrated circuit device assembly 2100 may take the form of any suitable ones of the embodiments of the integrated circuit components 100 disclosed herein.

In some embodiments, the circuit board 2102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 2102. In other embodiments, the circuit board 2102 may be a non-PCB substrate. In some embodiments the circuit board 2102 may be, for example, the circuit board 104. The integrated circuit device assembly 2100 illustrated in FIG. 21 includes a package-on-interposer structure 2136 coupled to the first face 2140 of the circuit board 2102 by coupling components 2116. The coupling components 2116 may electrically and mechanically couple the package-on-interposer structure 2136 to the circuit board 2102, and may include solder balls (as shown in FIG. 21), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 2116 may serve as the coupling components illustrated or described for any of the substrate assembly or substrate assembly components described herein, as appropriate.

The package-on-interposer structure 2136 may include an integrated circuit component 2120 coupled to an interposer 2104 by coupling components 2118. The coupling components 2118 may take any suitable form for the application, such as the forms discussed above with reference to the coupling components 2116. Although a single integrated circuit component 2120 is shown in FIG. 21, multiple integrated circuit components may be coupled to the interposer 2104; indeed, additional interposers may be coupled to the interposer 2104. The interposer 2104 may provide an intervening substrate used to bridge the circuit board 2102 and the integrated circuit component 2120.

The integrated circuit component 2120 may be a packaged or unpacked integrated circuit product that includes one or more integrated circuit dies (e.g., the die 1802 of FIG. 18, the integrated circuit device 1900 of FIG. 19) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 2120, a single monolithic integrated circuit die comprises solder bumps attached to contacts on the die. The solder bumps allow the die to be directly attached to the interposer 2104. The integrated circuit component 2120 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 2120 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 2120 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 2120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 2104 may spread connections to a wider pitch or reroute a connection to a different connection. For example, the interposer 2104 may couple the integrated circuit component 2120 to a set of ball grid array (BGA) conductive contacts of the coupling components 2116 for coupling to the circuit board 2102. In the embodiment illustrated in FIG. 21, the integrated circuit component 2120 and the circuit board 2102 are attached to opposing sides of the interposer 2104; in other embodiments, the integrated circuit component 2120 and the circuit board 2102 may be attached to a same side of the interposer 2104. In some embodiments, three or more components may be interconnected by way of the interposer 2104.

In some embodiments, the interposer 2104 may be formed as a PCB, including multiple metal layers separated from one another by layers of dielectric material and interconnected by electrically conductive vias. In some embodiments, the interposer 2104 may be formed of an epoxy resin, a fiberglass-reinforced epoxy resin, an epoxy resin with inorganic fillers, a ceramic material, or a polymer material such as polyimide. In some embodiments, the interposer 2104 may be formed of alternate rigid or flexible materials that may include the same materials described above for use in a semiconductor substrate, such as silicon, germanium, and other group III-V and group IV materials. The interposer 2104 may include metal interconnects 2108 and vias 2110, including but not limited to through hole vias 2110-1 (that extend from a first face 2150 of the interposer 2104 to a second face 2154 of the interposer 2104), blind vias 2110-2 (that extend from the first or second faces 2150 or 2154 of the interposer 2104 to an internal metal layer), and buried vias 2110-3 (that connect internal metal layers).

In some embodiments, the interposer 2104 can comprise a silicon interposer. Through silicon vias (TSV) extending through the silicon interposer can connect connections on a first face of a silicon interposer to an opposing second face of the silicon interposer. In some embodiments, an interposer 2104 comprising a silicon interposer can further comprise one or more routing layers to route connections on a first face of the interposer 2104 to an opposing second face of the interposer 2104.

The interposer 2104 may further include embedded devices 2114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2104. The package-on-interposer structure 2136 may take the form of any of the package-on-interposer structures known in the art.

The integrated circuit device assembly 2100 may include an integrated circuit component 2124 coupled to the first face 2140 of the circuit board 2102 by coupling components 2122. The coupling components 2122 may take the form of any of the embodiments discussed above with reference to the coupling components 2116, and the integrated circuit component 2124 may take the form of any of the embodiments discussed above with reference to the integrated circuit component 2120.

The integrated circuit device assembly 2100 illustrated in FIG. 21 includes a package-on-package structure 2134 coupled to the second face 2142 of the circuit board 2102 by coupling components 2128. The package-on-package structure 2134 may include an integrated circuit component 2126 and an integrated circuit component 2132 coupled together by coupling components 2130 such that the integrated circuit component 2126 is disposed between the circuit board 2102 and the integrated circuit component 2132. The coupling components 2128 and 2130 may take the form of any of the embodiments of the coupling components 2116 discussed above, and the integrated circuit components 2126 and 2132 may take the form of any of the embodiments of the integrated circuit component 2120 discussed above. The package-on-package structure 2134 may be configured in accordance with any of the package-on-package structures known in the art.

FIG. 22 is a block diagram of an example electrical device 2200 that may include one or more of the integrated circuit components 100 disclosed herein. For example, any suitable ones of the components of the electrical device 2200 may include one or more of the integrated circuit device assemblies 2100, integrated circuit components 2120, integrated circuit devices 1900, or integrated circuit dies 1802 disclosed herein, and may be arranged in any of the integrated circuit components 100 disclosed herein. A number of components are illustrated in FIG. 22 as included in the electrical device 2200, but any one or more of these components may be omitted or duplicated, as suitable for the application. In some embodiments, some or all of the components included in the electrical device 2200 may be attached to one or more motherboards mainboards, or system boards. In some embodiments, one or more of these components are fabricated onto a single system-on-a-chip (SoC) die.

Additionally, in various embodiments, the electrical device 2200 may not include one or more of the components illustrated in FIG. 22, but the electrical device 2200 may include interface circuitry for coupling to the one or more components. For example, the electrical device 2200 may not include a display device 2206, but may include display device interface circuitry (e.g., a connector and driver circuitry) to which a display device 2206 may be coupled. In another set of examples, the electrical device 2200 may not include an audio input device 2224 or an audio output device 2208, but may include audio input or output device interface circuitry (e.g., connectors and supporting circuitry) to which an audio input device 2224 or audio output device 2208 may be coupled.

The electrical device 2200 may include one or more processor units 2202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 2202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 2200 may include a memory 2204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 2204 may include memory that is located on the same integrated circuit die as the processor unit 2202. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 2200 can comprise one or more processor units 2202 that are heterogeneous or asymmetric to another processor unit 2202 in the electrical device 2200. There can be a variety of differences between the processing units 2202 in a system in terms of a spectrum of metrics of merit including architectural, microarchitectural, thermal, power consumption characteristics, and the like. These differences can effectively manifest themselves as asymmetry and heterogeneity among the processor units 2202 in the electrical device 2200.

In some embodiments, the electrical device 2200 may include a communication component 2212 (e.g., one or more communication components). For example, the communication component 2212 can manage wireless communications for the transfer of data to and from the electrical device 2200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 2212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 2212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 2212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 2212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 2212 may operate in accordance with other wireless protocols in other embodiments. The electrical device 2200 may include an antenna 2222 to facilitate wireless communications and/or to receive other wireless communications (such as AM or FM radio transmissions).

In some embodiments, the communication component 2212 may manage wired communications, such as electrical, optical, or any other suitable communication protocols (e.g., IEEE 802.3 Ethernet standards). As noted above, the communication component 2212 may include multiple communication components. For instance, a first communication component 2212 may be dedicated to shorter-range wireless communications such as Wi-Fi or Bluetooth, and a second communication component 2212 may be dedicated to longer-range wireless communications such as global positioning system (GPS), EDGE, GPRS, CDMA, WiMAX, LTE, EV-DO, or others. In some embodiments, a first communication component 2212 may be dedicated to wireless communications, and a second communication component 2212 may be dedicated to wired communications.

The electrical device 2200 may include battery/power circuitry 2214. The battery/power circuitry 2214 may include one or more energy storage devices (e.g., batteries or capacitors) and/or circuitry for coupling components of the electrical device 2200 to an energy source separate from the electrical device 2200 (e.g., AC line power).

The electrical device 2200 may include a display device 2206 (or corresponding interface circuitry, as discussed above). The display device 2206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 2200 may include an audio output device 2208 (or corresponding interface circuitry, as discussed above). The audio output device 2208 may include any embedded or wired or wirelessly connected external device that generates an audible indicator, such speakers, headsets, or earbuds.

The electrical device 2200 may include an audio input device 2224 (or corresponding interface circuitry, as discussed above). The audio input device 2224 may include any embedded or wired or wirelessly connected device that generates a signal representative of a sound, such as microphones, microphone arrays, or digital instruments (e.g., instruments having a musical instrument digital interface (MIDI) output). The electrical device 2200 may include a Global Navigation Satellite System (GNSS) device 2218 (or corresponding interface circuitry, as discussed above), such as a Global Positioning System (GPS) device. The GNSS device 2218 may be in communication with a satellite-based system and may determine a geolocation of the electrical device 2200 based on information received from one or more GNSS satellites, as known in the art.

The electrical device 2200 may include an other output device 2210 (or corresponding interface circuitry, as discussed above). Examples of the other output device 2210 may include an audio codec, a video codec, a printer, a wired or wireless transmitter for providing information to other devices, or an additional storage device.

The electrical device 2200 may include an other input device 2220 (or corresponding interface circuitry, as discussed above). Examples of the other input device 2220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 2200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 2200 may be any other electronic device that processes data. In some embodiments, the electrical device 2200 may comprise multiple discrete physical components. Given the range of devices that the electrical device 2200 can be manifested as in various embodiments, in some embodiments, the electrical device 2200 can be referred to as a computing device or a computing system.

### Examples

Illustrative examples of the technologies disclosed herein are provided below. An embodiment of the technologies may include any one or more, and any combination of, the examples described below.

Example 1 includes an integrated circuit component comprising one or more dies comprising a plurality of contact pads; a redistribution layer comprising a plurality of contact pads; and a release layer comprising a plurality of conductive pads, wherein individual conductive pads of the plurality of conductive pads connect one of the plurality of contact pads of the one or more dies to one of the plurality of contact pads of the redistribution layer; and a dielectric layer, wherein, below a first threshold temperature, the release layer secures the one or more dies to the redistribution layer, wherein the first threshold temperature is at least 280° C., wherein, above a second threshold temperature, the release layer is to release the one or more dies from the redistribution layer, wherein the one or more dies are able to withstand a temperature at the second threshold temperature.

Example 2 includes the subject matter of Example 1, and wherein the plurality of conductive pads of the release layer comprise gold and tin.

Example 3 includes the subject matter of any of Examples 1 and 2, and wherein the plurality of conductive pads of the release layer comprise at least 75% gold by weight and at least 15% tin by weight.

Example 4 includes the subject matter of any of Examples 1-3, and wherein the plurality of conductive pads of the release layer comprises a solder with a melting point between 290° C. and 350° C.

Example 5 includes the subject matter of any of Examples 1-4, and wherein the dielectric layer of the release layer comprises a polymer.

Example 6 includes the subject matter of any of Examples 1-5, and wherein the dielectric layer of the release layer has a melting point between 290° C. and 350° C.

Example 7 includes the subject matter of any of Examples 1-6, and wherein the dielectric layer of the release layer comprises polytetrafluoroethylene (PTFE).

Example 8 includes the subject matter of any of Examples 1-7, and wherein the dielectric layer of the release layer comprises one or more cyclobutanes.

Example 9 includes the subject matter of any of Examples 1-8, and wherein the dielectric layer of the release layer comprises polyimide.

Example 10 includes the subject matter of any of Examples 1-9, and wherein individual contact pads of the plurality of contact pads of the redistribution layer comprise a first side and a second side opposite the first side, wherein, for individual contact pads of the plurality of contact pads of the redistribution layer, the first side is adjacent a conductive pad of the plurality of conductive pads, wherein, for individual contact pads of the plurality of contact pads of the redistribution layer, the second side is at least partially covered by the dielectric layer.

Example 11 includes the subject matter of any of Examples 1-10, and wherein the dielectric layer has a thickness less than 5 micrometers.

Example 12 includes the subject matter of any of Examples 1-11, and further including a bridge die coupled to the redistribution layer; a backside redistribution layer coupled to the bridge die; and one or more solder balls coupled to the backside redistribution layer.

Example 13 includes the subject matter of any of Examples 1-12, and wherein the redistribution layer is a backside redistribution layer, further comprising one or more solder balls coupled to the backside redistribution layer.

Example 14 includes an integrated circuit component comprising one or more dies; a redistribution layer; and a release layer means comprising means for electrically connecting the one or more dies to the redistribution layer; and means for electrically isolating at least part of the one or more dies from at least part of the redistribution layer, wherein, below a first threshold temperature, the release layer means secures the one or more dies to the redistribution layer, wherein the first threshold temperature is at least 280° C., wherein, above a second threshold temperature, the release layer means is to release the one or more dies from the redistribution layer, wherein the one or more dies are able to withstand a temperature at the second threshold temperature.

Example 15 includes the subject matter of Example 14, and wherein the means for electrically connecting the one or more dies to the redistribution layer comprise gold and tin.

Example 16 includes the subject matter of any of Examples 14 and 15, and wherein the means for electrically connecting the one or more dies to the redistribution layer comprise at least 75% gold by weight and at least 15% tin by weight.

Example 17 includes the subject matter of any of Examples 14-16, and wherein the means for electrically connecting the one or more dies to the redistribution layer comprises a solder with a melting point between 290° C. and 350° C.

Example 18 includes the subject matter of any of Examples 14-17, and wherein the means for electrically isolating at least part of the one or more dies from at least part of the redistribution layer comprises a polymer.

Example 19 includes the subject matter of any of Examples 14-18, and wherein the means for electrically isolating at least part of the one or more dies from at least part of the redistribution layer has a melting point between 290° C. and 350° C.

Example 20 includes the subject matter of any of Examples 14-19, and wherein the means for electrically isolating at least part of the one or more dies from at least part of the redistribution layer comprises polytetrafluoroethylene (PTFE).

Example 21 includes the subject matter of any of Examples 14-20, and wherein means for electrically isolating at least part of the one or more dies from at least part of the redistribution layer comprises one or more cyclobutanes.

Example 22 includes the subject matter of any of Examples 14-21, and wherein the means for electrically isolating at least part of the one or more dies from at least part of the redistribution layer comprises polyimide.

Example 23 includes the subject matter of any of Examples 14-22, and wherein the means for electrically connecting the one or more dies to the redistribution layer comprises a plurality of conductive pads, wherein the redistribution layer comprises a plurality of contact pads, wherein the plurality of contact pads of the redistribution layer comprise a first side and a second side opposite the first side, wherein, for individual contact pads of the plurality of contact pads of the redistribution layer, the first side is adjacent a conductive pad of the plurality of conductive pads, wherein, for individual contact pads of the plurality of contact pads of the redistribution layer, the second side is at least partially covered by the means for electrically isolating at least part of the one or more dies from at least part of the redistribution layer.

Example 24 includes the subject matter of any of Examples 14-23, and wherein the means for electrically isolating at least part of the one or more dies from at least part of the redistribution layer has a thickness less than 5 micrometers.

Example 25 includes the subject matter of any of Examples 14-24, and further including a bridge die coupled to the redistribution layer; a backside redistribution layer coupled to the bridge die; and one or more solder balls coupled to the backside redistribution layer.

Example 26 includes the subject matter of any of Examples 14-25, and wherein the redistribution layer is a backside redistribution layer, further comprising one or more solder balls coupled to the backside redistribution layer.

Example 27 includes a method comprising forming a release layer on one or more dies; forming a redistribution layer on the release layer; determining that the redistribution layer is faulty; in response to a determination that the redistribution layer is faulty, heating up the release layer above a threshold temperature; and removing the one or more dies from the redistribution layer while the release layer is above the threshold temperature.

Example 28 includes the subject matter of Example 27, and further including forming a second release layer on one or more dies after removing the one or more dies from the redistribution layer; forming a second redistribution layer on the second release layer; and determining that the second redistribution layer is not faulty.

Example 29 includes the subject matter of any of Examples 27 and 28, and wherein forming the redistribution layer on the release layer comprises heating up the one or more dies and the release layer to a temperature of over 260° C.

Example 30 includes the subject matter of any of Examples 27-29, and wherein forming the release layer comprises forming a seed layer of copper on the one or more dies; depositing a lamination layer on the seed layer; patterning the lamination layer to form a plurality of holes in the lamination layer; depositing a plurality of conductive pads in the plurality of holes, wherein the plurality of conductive pads have a melting point of at least 280° C.; and depositing a plurality of copper pads on the plurality of conductive pads.

Example 31 includes the subject matter of any of Examples 27-30, and further including depositing a dielectric layer on the one or more dies; and thinning the dielectric layer to expose the plurality of copper pads.

Example 32 includes the subject matter of any of Examples 27-31, and further including depositing a dielectric layer on the one or more dies and the plurality of copper pads, wherein the dielectric layer has a thickness less than five micrometers; and laser drilling or dry etching the dielectric layer to expose the plurality of copper pads.

Example 33 includes the subject matter of any of Examples 27-32, and wherein plurality of conductive pads of the release layer comprise gold and tin.

Example 34 includes the subject matter of any of Examples 27-33, and wherein the plurality of conductive pads of the release layer comprise at least 75% gold by weight and at least 15% tin by weight.

Example 35 includes the subject matter of any of Examples 27-34, and wherein plurality of conductive pads of the release layer comprises a solder with a melting point between 290° C. and 350° C.

Example 36 includes the subject matter of any of Examples 27-35, and wherein a dielectric layer of the release layer comprises a polymer.

Example 37 includes the subject matter of any of Examples 27-36, and wherein a dielectric layer of the release layer has a melting point between 290° C. and 350° C.

Example 38 includes the subject matter of any of Examples 27-37, and wherein a dielectric layer of the release layer comprises polytetrafluoroethylene (PTFE).

Example 39 includes the subject matter of any of Examples 27-38, and wherein a dielectric layer of the release layer comprises one or more cyclobutanes.

Example 40 includes the subject matter of any of Examples 27-39, and wherein a dielectric layer of the release layer comprises polyimide.

Example 41 includes the subject matter of any of Examples 27-40, and wherein a plurality of contact pads of the redistribution layer comprise a first side and a second side opposite the first side, wherein, for individual contact pads of the plurality of contact pads of the redistribution layer, the first side is adjacent a conductive pad of a plurality of conductive pads of the release layer, wherein, for individual contact pads of the plurality of contact pads of the redistribution layer, the second side is at least partially covered by a dielectric layer of the release layer.

Example 42 includes the subject matter of any of Examples 27-41, and wherein the dielectric layer has a thickness less than 5 micrometers.

Example 43 includes the subject matter of any of Examples 27-42, and further including a bridge die coupled to the redistribution layer; a backside redistribution layer coupled to the bridge die; and one or more solder balls coupled to the backside redistribution layer.

Example 44 includes the subject matter of any of Examples 27-43, and wherein the redistribution layer is a backside redistribution layer, wherein one or more solder balls are coupled to the backside redistribution layer.

1. An integrated circuit component comprising:
one or more dies comprising a plurality of contact pads;
a redistribution layer comprising a plurality of contact pads; and
a release layer comprising:
a plurality of conductive pads, wherein individual conductive pads of the plurality of conductive pads connect one of the plurality of contact pads of the one or more dies to one of the plurality of contact pads of the redistribution layer; and
a dielectric layer,
wherein, below a first threshold temperature, the release layer secures the one or more dies to the redistribution layer, wherein the first threshold temperature is at least 280° C.,
wherein, above a second threshold temperature, the release layer is to release the one or more dies from the redistribution layer, wherein the one or more dies are able to withstand a temperature at the second threshold temperature.

2. The integrated circuit component of claim 1, wherein the plurality of conductive pads of the release layer comprise gold and tin.

3. The integrated circuit component of claim 2, wherein the plurality of conductive pads of the release layer comprise at least 75% gold by weight and at least 15% tin by weight.

4. The integrated circuit component of claim 1, wherein the plurality of conductive pads of the release layer comprises a solder with a melting point between 290° C. and 350° C.

5. The integrated circuit component of claim 1, wherein the dielectric layer of the release layer comprises a polymer.

6. The integrated circuit component of claim 1, wherein the dielectric layer of the release layer has a melting point between 290° C. and 350° C.

7. The integrated circuit component of claim 1, wherein the dielectric layer of the release layer comprises polytetrafluoroethylene (PTFE).

8. The integrated circuit component of claim 1, wherein the dielectric layer of the release layer comprises one or more cyclobutanes.

9. The integrated circuit component of claim 1, wherein the dielectric layer of the release layer comprises polyimide.

10. The integrated circuit component of claim 1, wherein individual contact pads of the plurality of contact pads of the redistribution layer comprise a first side and a second side opposite the first side, wherein, for individual contact pads of the plurality of contact pads of the redistribution layer, the first side is adjacent a conductive pad of the plurality of conductive pads, wherein, for individual contact pads of the plurality of contact pads of the redistribution layer, the second side is at least partially covered by the dielectric layer.

11. The integrated circuit component of claim 10, wherein the dielectric layer has a thickness less than 5 micrometers.

12. The integrated circuit component of claim 1, further comprising:
a bridge die coupled to the redistribution layer;
a backside redistribution layer coupled to the bridge die; and
one or more solder balls coupled to the backside redistribution layer.

13. The integrated circuit component of claim 1, wherein the redistribution layer is a backside redistribution layer, further comprising one or more solder balls coupled to the backside redistribution layer.

14. An integrated circuit component comprising:
one or more dies;
a redistribution layer; and
a release layer means comprising:
means for electrically connecting the one or more dies to the redistribution layer; and
means for electrically isolating at least part of the one or more dies from at least part of the redistribution layer,
wherein, below a first threshold temperature, the release layer means secures the one or more dies to the redistribution layer, wherein the first threshold temperature is at least 280° C.,
wherein, above a second threshold temperature, the release layer means is to release the one or more dies from the redistribution layer, wherein the one or more dies are able to withstand a temperature at the second threshold temperature.

15. The integrated circuit component of claim 14, wherein the means for electrically connecting the one or more dies to the redistribution layer comprise gold and tin.

16. The integrated circuit component of claim 14, wherein the means for electrically connecting the one or more dies to the redistribution layer comprises a solder with a melting point between 290° C. and 350° C.

17. The integrated circuit component of claim 14, wherein the means for electrically isolating at least part of the one or more dies from at least part of the redistribution layer has a melting point between 290° C. and 350° C.

18. An integrated circuit package comprising:
one or more dies comprising a plurality of contact pads;
a first dielectric layer comprising a plurality of contact pads; and
an intermediate layer comprising:
a plurality of conductive pads, wherein individual conductive pads of the plurality of conductive pads connect one of the plurality of contact pads of the one or more dies to one of the plurality of contact pads of the first dielectric layer, wherein the plurality of conductive pads comprise gold and tin; and
a second dielectric layer, wherein the second dielectric layer comprises carbon and fluorine.

18. The integrated circuit package of claim 18, wherein the plurality of conductive pads comprise at least 75% gold by weight and at least 15% tin by weight.

20. The integrated circuit package of claim 18, wherein the second dielectric layer comprises carbon and nitrogen.
